(19) United States
(12) Patent Application Publication
(10) Pub. No.: US 2019/0114170 A1
(43) Pub. Date: Apr. 18, 2019

(54) Processor Using Memory-Based Computation

(71) Applicant: Guobiao ZHANG, Corvallis, OR (US)

(72) Inventor: Guobiao ZHANG, Corvallis, OR (US)

(73) Assignee: HangZhou HaiCun Information Technology Co., Ltd., HangZhou (CN)

(21) Appl. No.: 16/188,265

(22) Filed: Nov. 12, 2018

Related U.S. Application Data
(63) Continuation-in-part of application No. 15/487,366, filed on Apr. 13, 2017.
Application No. 15/487,366 is a continuation-in-part of application No. 15/587,359, filed on May 4, 2017.
Application No. 15/587,359 is a continuation-in-part of application No. 15/587,362, filed on May 4, 2017.
Application No. 15/587,362 is a continuation-in-part of application No. 15/587,365, filed on May 4, 2017.
Application No. 15/587,365 is a continuation-in-part of application No. 15/587,369, filed on May 4, 2017.
Application No. 15/587,369 is a continuation-in-part of application No. 15/588,642, filed on May 6, 2017.
Application No. 15/588,642 is a continuation-in-part of application No. 15/588,643, filed on May 6, 2017.

(30) Foreign Application Priority Data
Feb. 13, 2016 (CN) 201610083747.7
Apr. 22, 2016 (CN) 201610260845.3
May 2, 2016 (CN) 201610289592.2
May 4, 2016 (CN) 201610294268.X
May 4, 2016 (CN) 201610294287.2
May 6, 2016 (CN) 201610301645.8
May 7, 2016 (CN) 201610300576.9
Apr. 12, 2017 (CN) 201710237780.5
May 2, 2017 (CN) 201710302427.0
May 2, 2017 (CN) 201710302436.X
May 3, 2017 (CN) 201710302440.6
May 3, 2017 (CN) 201710302446.3
May 5, 2017 (CN) 201710310865.1
May 5, 2017 (CN) 201710311013.4

(51) Int. Cl. G06F 9/30; G06F 1/03; G06F 17/50; G06F 17/11; H01L 27/02; G06F 12/02

(52) U.S. Cl. CPC G06F 9/3004; G06F 9/30014; G06F 1/03; G06F 12/0207; G06F 17/11; H01L 27/0207; G06F 17/5072

(57) ABSTRACT

Instead of logic-based computation (LBC), the preferred processor disclosed in the present invention uses memory-based computation (MBC). It comprises an array of computing elements, with each computing element comprising a memory array on a memory level for storing a look-up table (LUT) and an arithmetic logic circuit (ALC) on a logic level for performing arithmetic operations on selected LUT data. The memory level and the logic level are different physical levels.

### CROSS-REFERENCE TO RELATED APPLICATIONS

This application is a continuation-in-part of the following U.S. patent applications:

1) U.S. patent application Ser. No. 15/487,366, filed Apr. 13, 2017;

2) U.S. patent application Ser. No. 15/587,359, filed May 4, 2017;

3) U.S. patent application Ser. No. 15/587,362, filed May 4, 2017;

4) U.S. patent application Ser. No. 15/587,365, filed May 4, 2017;

5) U.S. patent application Ser. No. 15/587,369, filed May 4, 2017;

6) U.S. patent application Ser. No. 15/588,642, filed May 6, 2017;

7) U.S. patent application Ser. No. 15/588,643, filed May 6, 2017.

This application also claims priority from the following Chinese patent applications:

1) Chinese Patent Application 201610083747.7, filed on Feb. 13, 2016;

2) Chinese Patent Application 201610260845.3, filed on Apr. 22, 2016;

3) Chinese Patent Application 201610289592.2, filed on May 2, 2016;

4) Chinese Patent Application 201610294268.X, filed on May 4, 2016;

5) Chinese Patent Application 201610294287.2, filed on May 4, 2016;

6) Chinese Patent Application 201610301645.8, filed on May 6, 2016;

7) Chinese Patent Application 201610300576.9, filed on May 7, 2016;

8) Chinese Patent Application 201710237780.5, filed on Apr. 12, 2017;

9) Chinese Patent Application 201710302427.0, filed on May 2, 2017;

10) Chinese Patent Application 201710302436.X, filed on May 2, 2017;

11) Chinese Patent Application 201710302440.6, filed on May 3, 2017;

12) Chinese Patent Application 201710302446.3, filed on May 3, 2017;

13) Chinese Patent Application 201710310865.1, filed on May 5, 2017;

14) Chinese Patent Application 201710311013.4, filed on May 5, 2017;

in the State Intellectual Property Office of the People's Republic of China (CN), the disclosure of which are incorporated herein by references in their entireties.

### BACKGROUND

### 1. Technical Field of the Invention

The present invention relates to the field of integrated circuit, and more particularly to processors.

### 2. Prior Art

Conventional processors use logic-based computation (LBC), which carries out computation primarily with logic circuits (e.g. XOR circuit). Logic circuits are suitable for arithmetic functions, whose operations only consist of basic arithmetic operations, i.e. addition, subtraction and multiplication. However, logic circuits are not suitable for non-arithmetic functions, whose operations involve more than addition, subtraction and multiplication. Exemplary non-arithmetic functions include transcendental functions and special functions. Non-arithmetic functions are computationally hard and their hardware implementation has been a major challenge.

Throughout the present invention, the phrase “mathematical functions” refer to non-arithmetic functions; and, the implementation of mathematical functions is limited to hardware implementation of non-arithmetic functions. A complex function is a non-arithmetic function with multiple independent variables (independent variable is also known as input variable or argument). It can be expressed as a combination of basic functions. A basic function is a non-arithmetic function with a single independent variable. Exemplary basic functions include basic transcendental functions, such as exponential function (exp), logarithmic function (log), and trigonometric functions (sin, cos, tan, a tan).

The computation of non-arithmetic functions and model simulation has been a major challenge. In the following paragraphs, the background of the present invention is described in the fields of general computation, model simulation, and configurable computation.

A) General Computation

For the conventional processors, only few basic functions (e.g. basic algebraic functions and basic transcendental functions) are implemented by hardware and they are referred to as built-in functions. These built-in functions are realized by a combination of logic circuits and look-up table (LUT) memory. For example, U.S. Pat. No. 5,954,787 issued to Eun on Sep. 21, 1999 taught a method for generating sine/cosine functions using LUTs; U.S. Pat. No. 9,207,910 issued to Azadet et al. on Dec. 8, 2015 taught a method for calculating a power function using LUTs.

Realization of built-in functions is further illustrated in FIG. 1A. A conventional processor 00X generally comprises a logic circuit 100X and a memory circuit 200X. The logic circuit 100X comprises an arithmetic logic unit (ALU) for performing basic arithmetic operations (i.e. addition, subtraction, multiplication), whereas the memory circuit 200X stores a look-up table (LUT) including numerical values related to the built-in function. To achieve a desired precision, the built-in function is approximated to a polynomial of a sufficiently high order. The memory circuit 200X stores the coefficients of the polynomial; and the logic circuit 100X calculates the polynomial. Because the logic circuit 100X and the memory circuit 200X are formed side-by-side on a semiconductor substrate 00S, this type of horizontal integration is referred to as two-dimensional (2-D) integration.

The 2-D integration puts stringent requirements on the manufacturing process. As is well known in the art, the memory transistors in the memory circuit 200X are vastly different from the logic transistors in the ALC 100X. The memory transistors have stringent requirements on leakage current, while the logic transistors have stringent requirements on drive current. To form high-performance memory transistors and high-performance logic transistors on the same surface of the semiconductor substrate 00S at the same time is a challenge.

The 2-D integration also limits computational density and computational complexity. Computation has been developed towards higher computational density and greater computational complexity. The computational density, i.e. the computational power (e.g. the number of floating-point operations per second) per die area, is a figure of merit for parallel computation. The computational complexity, i.e. the total number of built-in functions supported by a processor, is a figure of merit for scientific computation. For the 2-D integration, inclusion of the memory circuit 200X increases the die size of the conventional processor 00X and lowers its computational density. This has an adverse effect on parallel computation. Moreover, because the logic circuit 100X, as the primary component of the conventional processor 00X, occupies a large die area, the memory circuit 200X, occupying only a small die area, supports few built-in functions. FIG. 1B lists all built-in transcendental functions supported by an Intel Itanium (IA-64) processor (referring to Harrison et al. “The Computation of Transcendental Functions on the IA-64 Architecture”, Intel Technical journal, Q4 1999, hereinafter Harrison). The IA-64 processor supports a total of 7 built-in transcendental functions, each using a relatively small LUT (from 0 to 24 kb) in conjunction with a relatively high-order Taylor series (from 5 to 22).

B) Model Simulation

This small set of built-in functions (˜10 types, including arithmetic operations) is the foundation of scientific computation. Scientific computation uses advanced computation capabilities to advance human understandings and solve engineering problems. It has wide applications in computational mathematics, computational physics, computational chemistry, computational biology, computational engineering, computational economics, computational finance and other computational fields. The prevailing framework of scientific computation comprises three layers: a foundation layer, a function layer and a modeling layer. The foundation layer includes built-in functions that can be implemented by hardware. The function layer includes mathematical functions that cannot be implemented by hardware. The modeling layer includes mathematical models of a system to be simulated (e.g. an electrical amplifier) or a system component to be modeled (e.g. a transistor in the electrical amplifier). The mathematical models are the mathematical descriptions of the input-output characteristics of the system to be simulated or the system component to be modeled. They could be either the measurement data (e.g. raw measurement data, or smoothed measurement data), or the mathematical expressions extracted from the raw measurement data.

In prior art, the mathematical functions in the function layer and the mathematical models in the modeling layer are implemented by software. The function layer involves one software-decomposition step: mathematical functions are decomposed into combinations of built-in functions by software, before these built-in functions and the associated arithmetic operations are calculated by hardware. The modeling layer involves two software-decomposition steps: the mathematical models are first decomposed into combinations of mathematical functions; then the mathematical functions are further decomposed into combinations of built-in functions. Apparently, the software-implemented functions (e.g. mathematical functions, mathematical models) run much slower and less efficient than the hardware-implemented functions (i.e. built-in functions). Moreover, because more software-decomposition steps lead to more computation, the mathematical models (with two software-decomposition steps) suffer longer delay and more energy consumption than the mathematical functions (with one software-decomposition step).

To illustrate the computational complexity of a mathematical model, FIGS. 2A-2B disclose a simple example—the simulation of an electrical amplifier 20. The system to be simulated, i.e. the electrical amplifier 20, comprises two system components, i.e. a resistor 22 and a transistor 24 (FIG. 2A). The mathematical models of transistors (e.g. MOS3, BSIM3, BSIM4, PSP) are based on the small set of built-in functions supported by the conventional processor 00X, i.e. they are expressed by a combination of these built-in functions. Due to the limited choice of the built-in functions, calculating even a single current-voltage (I-V) point for the transistor 24 requires a large amount of computation (FIG. 2B). As an example, the BSIM4 transistor model needs 222 additions, 286 multiplications, 85 divisions, 16 square-root operations, 24 exponential operations, and 19 logarithmic operations. This large amount of computation makes modeling and simulation extremely slow and inefficient.

C) Configurable Computation

The conventional processor 00X suffers another drawback. Because different logic circuits are used to realize different built-in functions, the conventional processor 00X is fully customized. In other words, once its design is complete, the conventional processor 00X can only realize a fixed set of pre-defined built-in functions. Apparently, configurable computation is more desirable, where a same hardware can realize different mathematical functions under the control of a set of configuration signals.

In the past, configurable logic, i.e. a same hardware realizes different logics under the control of a set of configuration signals, was realized by configurable gate array (e.g. field-programmable gate array). U.S. Pat. No. 4,870,302 issued to Freeman on Sep. 26, 1989 (hereinafter Freeman) discloses a configurable gate array. It comprises an array of configurable logic elements and a hierarchy of configurable interconnects that allow the configurable logic elements to be wired together. In the prior-art configurable gate arrays, mathematical functions are still realized in fixed computing elements, which are part of hard blocks and not configurable, i.e. the circuits realizing these mathematical functions are fixedly connected and are not subject to change by programming. Apparently, fixed computing elements would limit applications of the configurable gate array.

### Objects and Advantages

It is a principle object of the present invention to provide a paradigm shift for scientific computation.

It is a further object of the present invention to provide a processor with improved computational complexity.

It is a further object of the present invention to provide a processor with improved computational density.

It is a further object of the present invention to provide a processor with improved computational configurability.

It is a further object of the present invention to provide a processor with a large set of built-in functions.

It is a further object of the present invention to realize rapidly and efficient implementation of non-arithmetic functions.

It is a further object of the present invention to realize rapid and efficient modeling and simulation.

It is a further object of the present invention to realize configurable computation.

In accordance with these and other objects of the present invention, the present invention discloses a processor using memory-based computation (MBC), i.e. MBC-processor.

### SUMMARY OF THE INVENTION

The present invention discloses a processor using memory-based computation (MBC), i.e. MBC-processor. It comprises an array of computing elements, with each computing element comprising a memory for storing at least a portion of a look-up table (LUT) for a mathematical function (i.e. LUT memory) and an arithmetic logic circuit (ALC) for performing arithmetic operations on the LUT data. The LUT memory comprises at least a memory array disposed on a memory level, whereas the ALC is disposed on a logic level different from the memory level. The memory array is communicatively coupled with the ALC through a plurality of inter-level connections.

The preferred MBC-processor uses memory-based computation (MBC), which carries out computation primarily with the LUT stored in the LUT memory. Because it uses a much larger LUT than the logic-based computation (LBC) as a starting point, the preferred MBC-processor only needs to calculate a polynomial to a smaller order. Overall, in the preferred MBC-processor, the fraction of computation done by the MBC is substantially more than the LBC.

In the preferred MBC-processor, the logic level and the memory level are different physical levels. This type of integration is referred to as vertical integration. The vertical integration has a profound effect on the computational density. Because the memory cells of the LUT memory are not located on the logic level, the footprint of the computing element is roughly equal to that of the ALC. This is much smaller than the footprint of a conventional processor, which is roughly equal to the sum of the footprints of the ALU and the LUT memory. By moving the memory cells of the LUT memory from aside to above, the computing element becomes much smaller. As a result, the preferred MBC-processor would contain more computing elements, become more computationally powerful and support massive parallelism.

The vertical integration also has a profound effect on the computational complexity. For a conventional processor, the total LUT capacity is less than 100 kb. In contrast, the total LUT capacity for the preferred MBC-processor could reach 100 Gb (for example, a 3D-XPoint die has a storage capacity of 128 Gb). Consequently, the preferred MBC-processor could support as many as 10,000 built-in functions, which are significantly more than the conventional processor.

Significantly more built-in functions shall flatten the prevailing framework of scientific computation (including the foundation, function and modeling layers). The hardware-implemented functions, which were only available to the foundation layer in the past, now become available to the function and modeling layers. Not only the mathematical functions in the function layer can be directly realized by hardware, but also the mathematical models in the modeling layer. In the function layer, the mathematical functions can be realized by a function-by-LUT method, i.e. the functional values are calculated by interpolating the function-related data stored in the LUT memory. In the modeling layer, the mathematical models can be realized by a model-by-LUT method, i.e. the input-output characteristics of a system component are modeled by interpolating the model-related data stored in the LUT memory. This would lead to a paradigm shift in scientific computation.

The best advantage of the memory-based computation (MBC) over the logic-based computation (LBC) is configurability and generality. By loading the LUTs of different mathematical functions into the LUT memory at different time, a single LUT memory can be used to implement a large set of mathematical functions, thus realizing configurable computation. Accordingly, the present invention discloses a configurable processor. It comprises at least an array of configurable computing elements, at least an array of configurable logic elements and at least an array of configurable interconnects. Each configurable computing element comprises at least a programmable memory for storing the LUT for a mathematical function. During operation, a complex function is first decomposed into a combination of basic functions. Each basic function is realized by programming an associated configurable computing element. The complex function is then realized by programming the appropriate configurable logic elements and configurable interconnects. Apparently, hardware computation of complex functions is much faster and more efficient than software computation.

Accordingly, the present invention discloses a processor, comprising: at least a memory array on a memory level for storing at least a portion of a look-up table (LUT) for a mathematical function; an arithmetic logic circuit (ALC) on a logic level for performing at least one arithmetic operation on selected data from said LUT; a plurality of inter-level connections for communicatively coupling said memory array and said ALC; wherein said memory level and said logic level are different physical levels.

The present invention further discloses a processor for simulating a system comprising a system component, comprising: at least a memory array for storing at least a portion of a look-up table (LUT) for a mathematical model of said system component; an arithmetic logic circuit (ALC) for performing at least one arithmetic operation on selected data from said LUT; means for communicatively coupling said memory array and said ALC.

### BRIEF DESCRIPTION OF THE DRAWINGS

FIG. 1A is a perspective view of a conventional processor (prior art); FIG. 1B lists all transcendental functions supported by an Intel Itanium (IA-64) processor (prior art);

FIG. 2A is a circuit diagram of an amplifier circuit; FIG. 2B lists number of operations to calculate a current-voltage (I-V) point for various transistor models (prior art);

FIG. 3 is a block diagram of a preferred MBC-processor;

FIG. 4A is a block diagram of a typical computing element; FIG. 4B is a perspective view of the typical computing element;

FIGS. 5A-5C are the block diagrams of three preferred ALCs;

FIG. 6A is a block diagram of a first preferred computing element; FIG. 6B is the circuit block view on the logic level; FIG. 6C is a circuit diagram of the first preferred computing element; FIG. 6D lists the LUT size and Taylor series required to realize mathematical functions with different precisions;

FIG. 7A is a block diagram of a second preferred computing element; FIG. 7B is the circuit block view on the logic level;

FIG. 8A is a block diagram of a third preferred computing element; FIG. 8B is the circuit block view on the logic level;

FIG. 9 is a block diagram of a preferred configurable processor;

FIG. 10 shows an instantiation of the first preferred configurable processor;

FIGS. 11A-11B are cross-sectional views of two preferred MBC-processor dice comprising three-dimensional horizontal memory (3D-M_{H}) arrays;

FIGS. 12A-12B are cross-sectional views of two preferred MBC-processor dice comprising three-dimensional vertical memory (3D-M_{V}) arrays;

FIGS. 13A-13C are the substrate layout views of three preferred computing elements;

FIGS. 14A-14C are different views of a preferred MBC-processor die using two-sided integration: FIG. 14A is a perspective view of its front side; FIG. 14B is a perspective view of its back side; FIG. 14C is its cross-sectional view;

FIG. 15 is a perspective view of a preferred MBC-processor package;

FIGS. 16A-16C are cross-sectional views of three preferred MBC-processor packages.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. The symbol “/” means a relationship of “and” or “or”.

Throughout the present invention, the phrase “memory” is used in its broadest sense to mean any semiconductor-based holding place for information; the phrase “communicatively coupled” is used in its broadest sense to mean any coupling whereby information may be passed from one element to another element; the phrase “on the substrate” means the active elements of a circuit (e.g. transistors) are formed on the surface of the substrate, although the interconnects between these active elements are formed above the substrate and do not touch the substrate; the phrase “above the substrate” means the active elements (e.g. memory cells) are formed above the substrate and do not touch the substrate.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

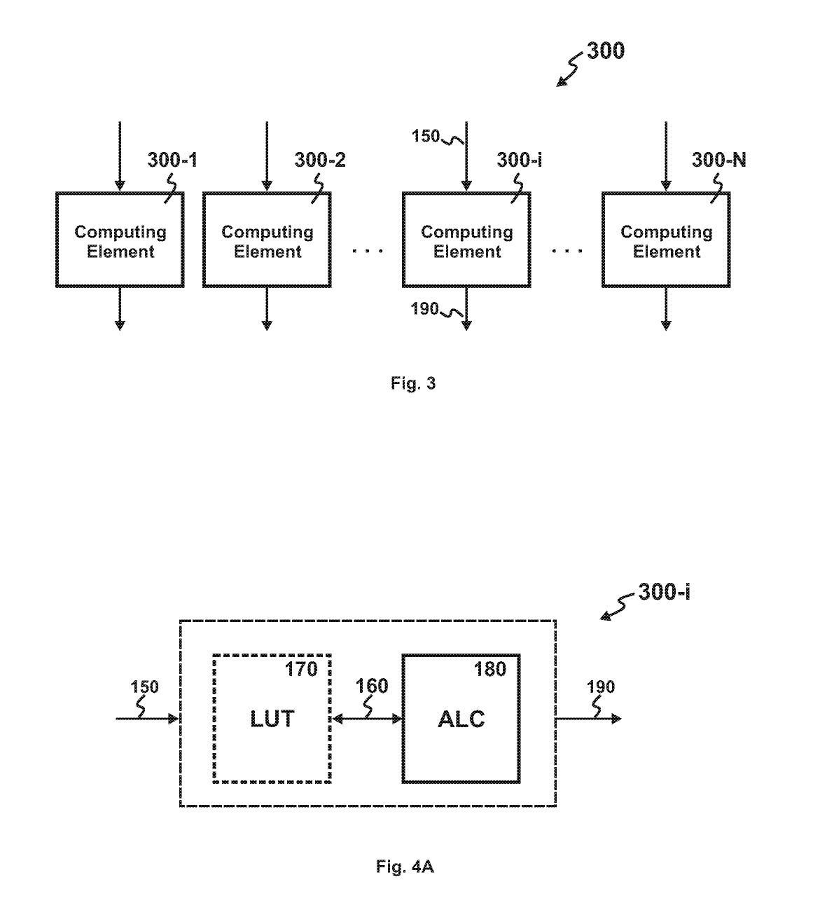

Referring now to FIG. 3, a preferred processor using memory-based computation (MBC), i.e. MBC-processor 300, is disclosed. The preferred MBC-processor 300 comprises an array of computing elements 300-1, 300-2 . . . 300-i . . . 300-N. These computing elements 300-1 . . . 300-N could realize a same mathematical function or different mathematical functions. Each computing element 300-i could have one or more input variables 150, and one or more output variables 190 (FIG. 3).

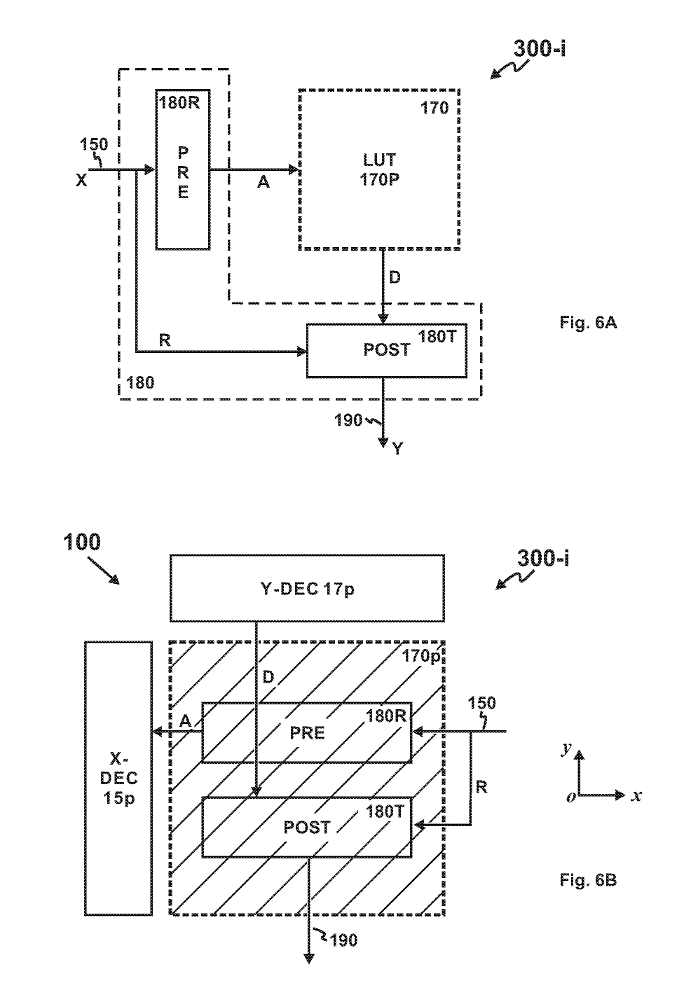

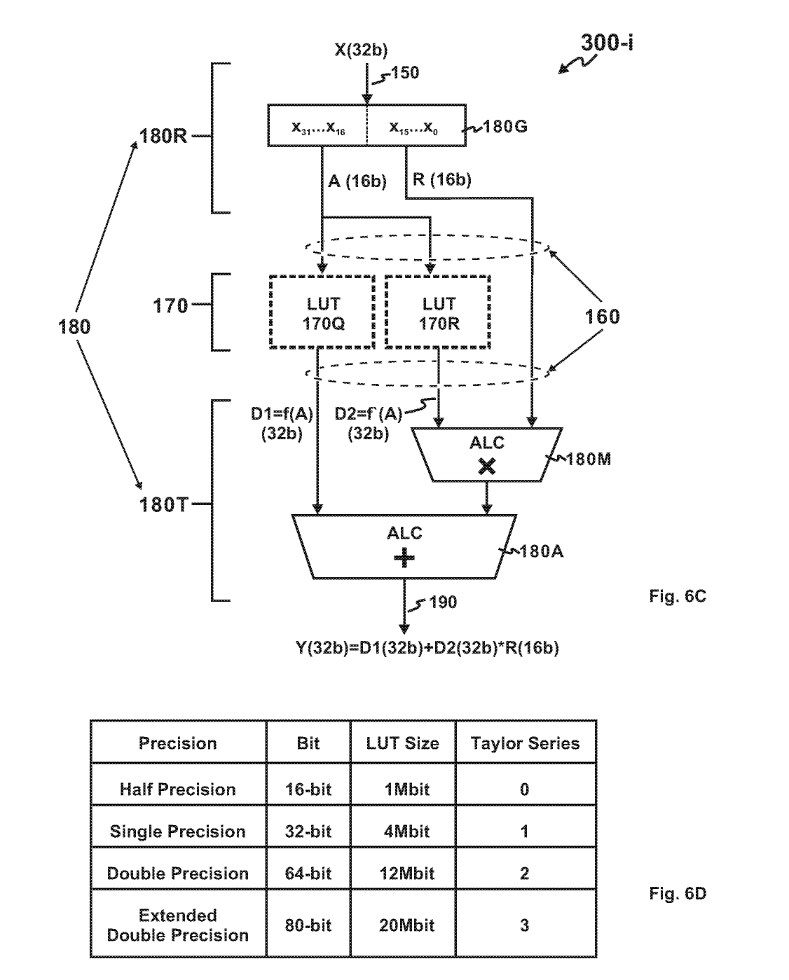

FIGS. 4A-4B disclose details on a typical computing element 300-i. It comprises a memory 170 for storing at least a portion of a look-up table (LUT) for a mathematical function (i.e. LUT memory 170); and, an arithmetic logic circuit (ALC) 180 for performing at least one arithmetic operation on selected LUT data (FIG. 4A). The memory cells of the LUT memory 170 are disposed on at least one memory level 200, whereas the logic transistors of the ALC 180 are disposed on at least one logic level 100. The memory level 200 and the logic level 100 are two different physical levels (FIG. 4B). In this preferred embodiment, the memory level 200 is stacked above the logic level 100. Alternatively, the logic level 100 may be stacked above the memory level 200. The computing element 300-i further comprises a plurality of inter-level connections 160 for communicatively coupling the LUT memory 170 and the ALC 180. Because the memory cells of the LUT memory 170 are disposed on a memory level 200 different than the logic level 100, it is represented by dashed line in FIG. 4A and following figures (FIGS. 6A-10, FIGS. 13A-13C).

The preferred MBC-processor 300 uses memory-based computation (MBC), which carries out computation primarily with the LUT stored in the LUT memory 170. Because it uses a much larger LUT than the logic-based computation (LBC) as a starting point, the preferred MBC-processor 300 only needs to calculate a polynomial to a smaller order. Overall, in the preferred MBC-processor, the fraction of computation done by the MBC is substantially more than the LBC.

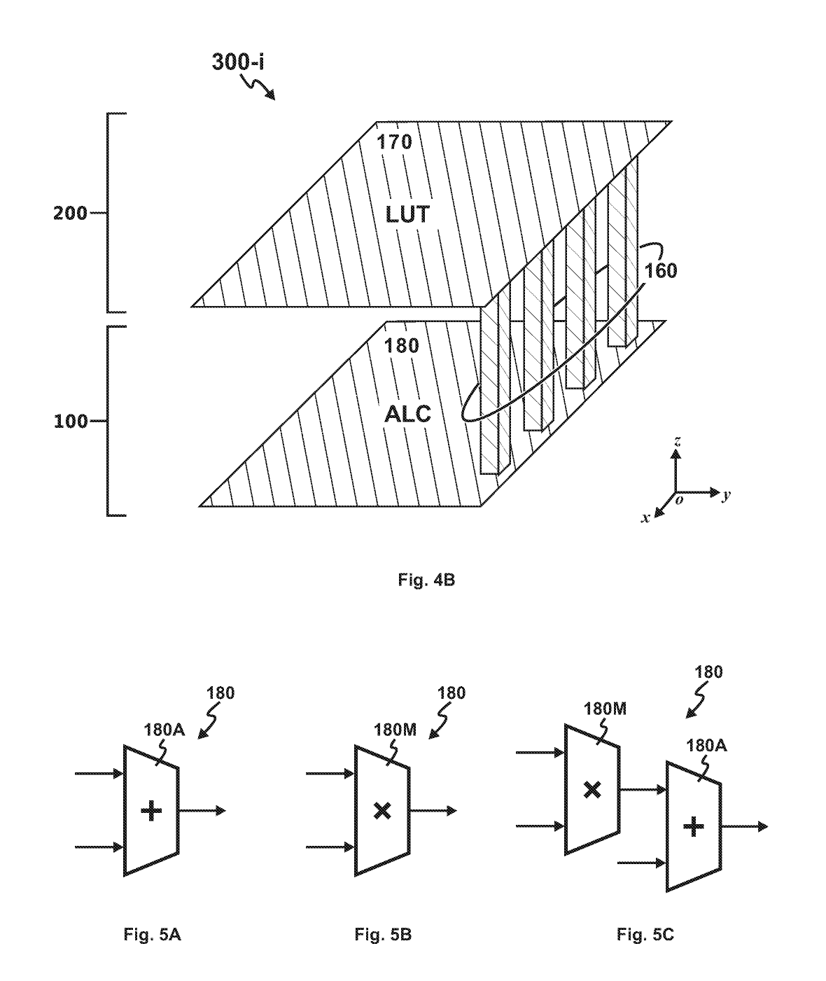

FIGS. 5A-5C disclose three preferred ALCs 180. The first preferred ALC 180 comprises an adder 180A (FIG. 5A), the second preferred ALC 180 comprises a multiplier 180M (FIG. 5B), with the third preferred ALC 180 comprising a multiplier-accumulator (MAC), which includes an adder 180A and a multiplier 180M (FIG. 5C). The logic circuits to implement the adder 180A, the multiplier 180M and/or the MAC 180 are well known to those skilled in the art.

Referring now to FIGS. 6A-6D, a first preferred computing element 300-i implementing a built-in function Y=f(X) is disclosed. It uses the function-by-LUT method. As is shown in FIG. 6A, the ALC 180 comprises a pre-processing circuit 180R and a post-processing circuit 180T, while the LUT memory 170 stores an LUT 170P. The pre-processing circuit 180R converts the input variable (X) 150 into an address (A) of the LUT memory 170. After the data (D) at the address (A) is read out from the LUT memory 170, the post-processing circuit 180T converts it into the functional value (Y) 190. A residue (R) of the input variable (X) is fed into the post-processing circuit 180T to improve the calculation precision.

FIG. 6B is the circuit block view on the logic level 100. The circuit blocks on the logic level 100 include the pre-processing circuit 180R, the post-processing circuit 180T, as well as the X-decoder 15p and the Y-decoder 17p of the LUT memory 170 (for some embodiments, the decoders may be disposed on the memory level 200). On the other hand, the circuit blocks on the memory level 200 include the memory array 170p storing the LUT 170P (which is represented by a dashed line). The memory array 170p is stacked above and at least partially covers the pre-processing circuit 180R and the post-processing circuit 180T. Although a single memory array 170p is shown in this figure, the preferred embodiment could comprise multiple memory arrays. Because the memory array 170p does not occupy any area on the logic level 100, the vertical integration between the LUT memory 170 and the ALC 180 leads to a small footprint for the computing element 300-i.

FIG. 6C discloses the first preferred computing element 300-i which realizes a single-precision built-in function Y=f(X). The input variable X 150 has 32 bits (x₃₁ . . . x₀). The pre-processing circuit 180R extracts the higher 16 bits (x₃₁ . . . x₁₆) thereof and sends it as a 16-bit address A to the LUT memory 170. The pre-processing circuit 180R further extracts the lower 16 bits (x₁₅ . . . x₀) and sends it as a 16-bit residue R to the post-processing circuit 180T. The LUT memory 170 stores two LUTs 170Q, 170R. Both LUTs 170Q, 170R have 2 Mb capacities (16-bit input and 32-bit output): the LUT 170Q includes the functional value D1=f(A), while the LUT 170R includes the first-order derivative value D2=f′(A). The post-processing circuit 180T comprises a multiplier 180M and an adder 180A. The output value (Y) 190 has 32 bits and is calculated from polynomial interpolation. In this case, the polynomial interpolation is a first-order Taylor series: Y(X)=D1+D2*R==f(A)+f′(A)*R. To those skilled in the art, higher-order polynomial interpolation (e.g. higher-order Taylor series) can be used to improve the calculation precision.

When calculating a built-in function, combining the LUT with polynomial interpolation can achieve a high precision without using an excessively large LUT. For example, if only LUT (without any polynomial interpolation) is used to realize a single-precision function (32-bit input and 32-bit output), it would have a capacity of 2³²*32=128 Gb, which is impractical. By including polynomial interpolation, significantly smaller LUTs can be used. FIG. 6D lists the LUT size and Taylor series required to realize mathematical functions with different precisions. For half precision (16-bit), only 1 Mb LUT is needed and no Taylor-series calculation is required. For single precision (32-bit), a total of 4 Mb LUT is needed, as well as one order of Taylor-series calculation. For double precision (64-bit), a total of 12 Mb LUT is needed, plus two orders of Taylor-series calculation. For extended double precision (80-bit), a total of 20 Mb and three orders of Taylor-series calculation are needed.

Besides elementary functions (e.g. algebraic functions, transcendental functions), the preferred embodiment of FIG. 6A-6D can be used to implement non-elementary functions such as special functions. Special functions can be defined by means of power series, generating functions, infinite products, repeated differentiation, integral representation, differential difference, integral, and functional equations, trigonometric series, or other series in orthogonal functions. Important examples of special functions are gamma function, beta function, hyper-geometric functions, confluent hyper-geometric functions, Bessel functions, Legrendre functions, parabolic cylinder functions, integral sine, integral cosine, incomplete gamma function, incomplete beta function, probability integrals, various classes of orthogonal polynomials, elliptic functions, elliptic integrals, Lame functions, Mathieu functions, Riemann zeta function, automorphic functions, and others. The preferred processor 300 will simplify the calculation of special functions and promote their applications in scientific computation.

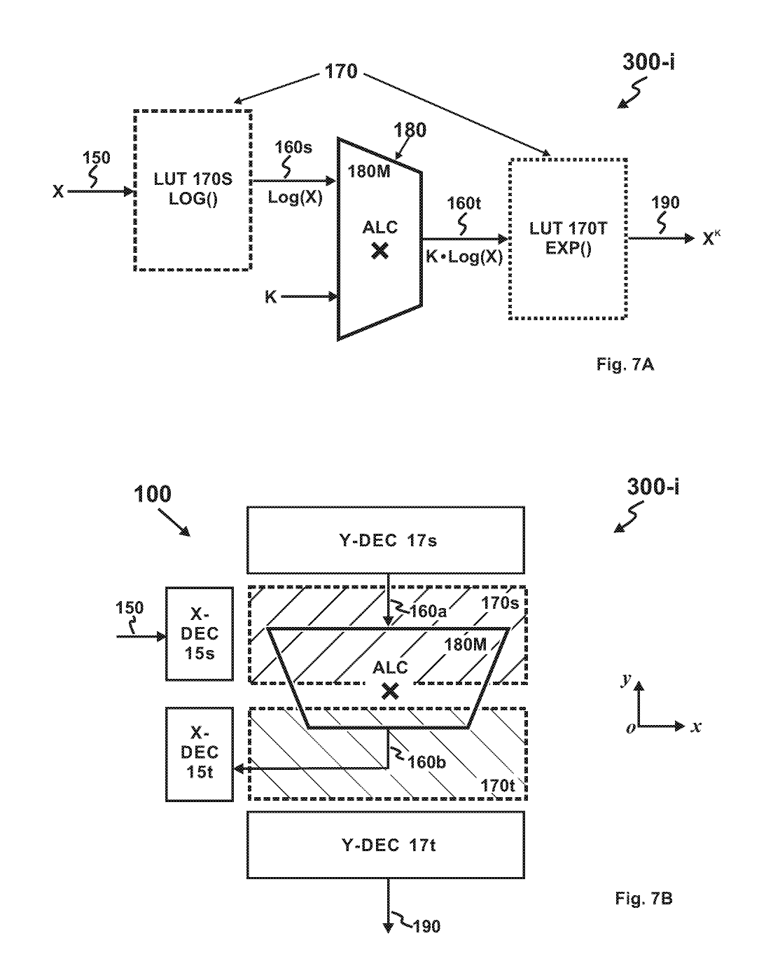

Referring now to FIGS. 7A-7B, a second preferred computing element 300-i implementing a composite function Y=exp[K*log(X)]=X^{K} is disclosed. It uses the function-by-LUT method. As is shown in FIG. 7A, the LUT memory 170 stores two LUTs 170S, 170T, while the ALC 180 comprises a multiplier 180M. The LUT 170S includes the log( ) values, while the LUT 170T includes the exp( ) values. The input variable X is used as an address 150 for the LUT 170S. The output log(X) 160a from the LUT 170S is multiplied by an exponent parameter K at the multiplier 180M. The multiplication result K*Log(X) is used as an address 160b for the LUT 170T, whose output 190 is Y=X^{K}.

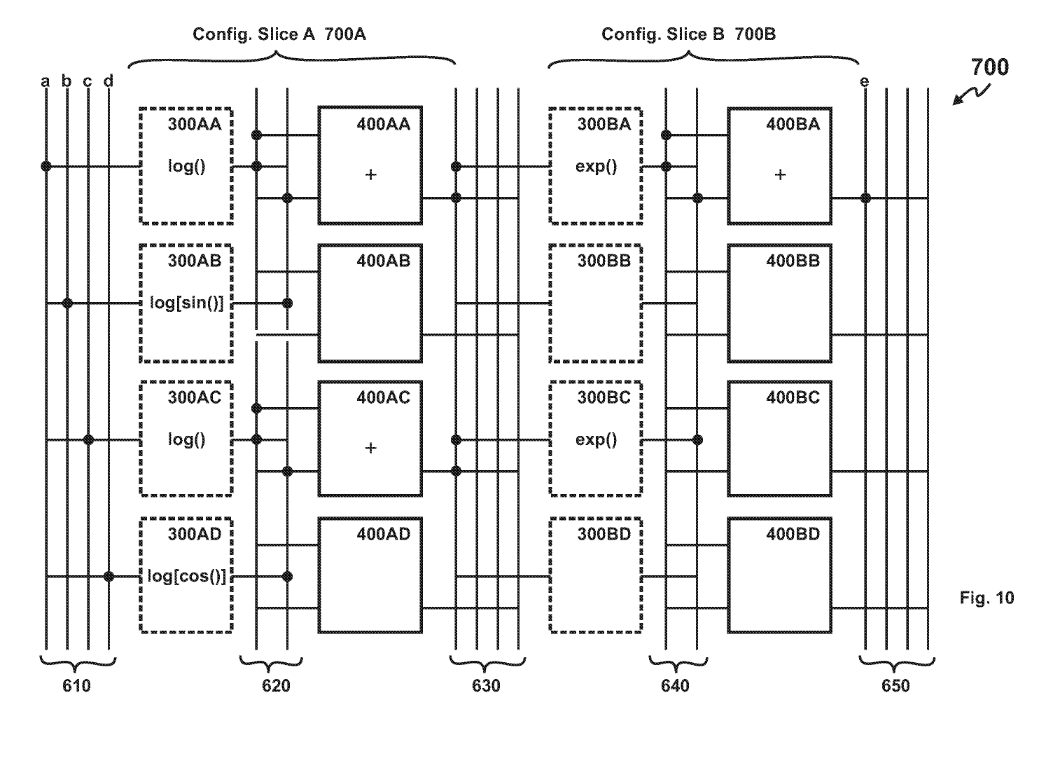

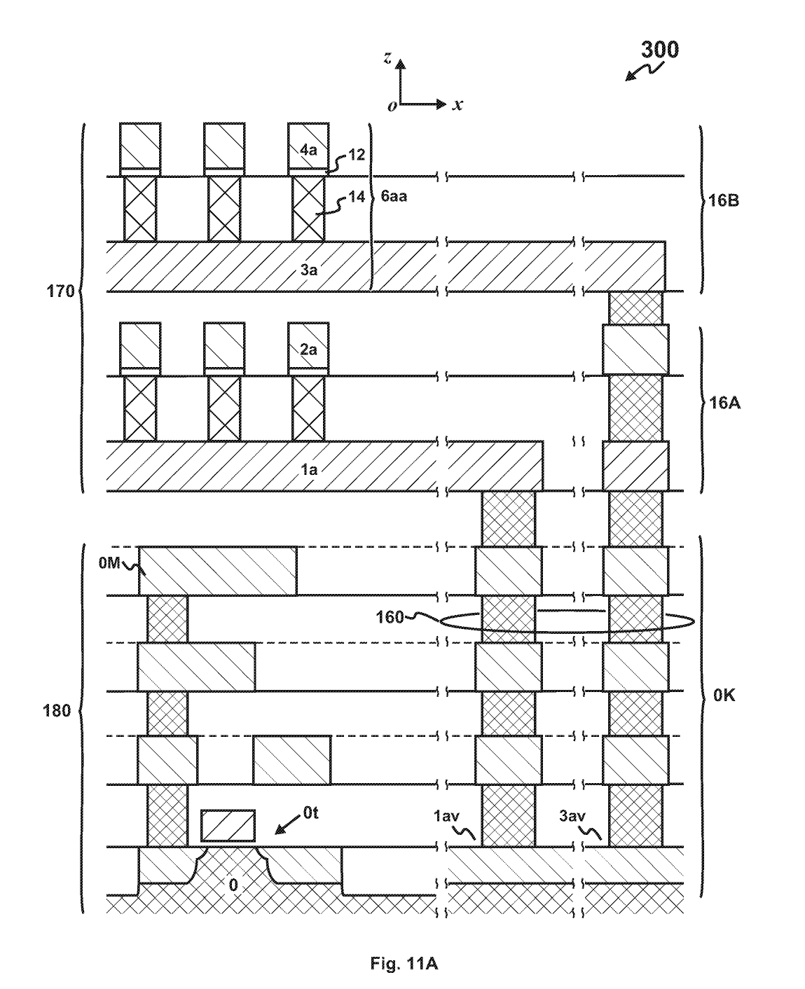

FIG. 7B is the circuit block view on the logic level 100. The circuit blocks on the logic level 100 include a multiplier 180M, as well as the X-decoders 15s, 15t and the Y-decoders 17s, 17t of the LUTs 170S, 170T (for some embodiments, the decoders may be disposed on the memory level 200). On the other hand, the circuit blocks on the memory level 200 include the memory arrays 170s, 170t storing the LUTs 170S, 170T (which are represented by dashed lines in this figure). Placed side-by-side, both memory arrays 170s, 170t are stacked above and at least partially cover the multiplier 180M. Note that both embodiments in FIG. 6C and FIG. 7A comprise two LUTs. These LUTs could be stored in a single memory array 170p (as in FIG. 6B), in two memory arrays 170s, 170t placed side-by-side (as in FIG. 7B), in two vertically stacked memory arrays (i.e. on different memory levels 16A, 16B, as in FIGS. 11A-11B), or in more than two memory arrays.

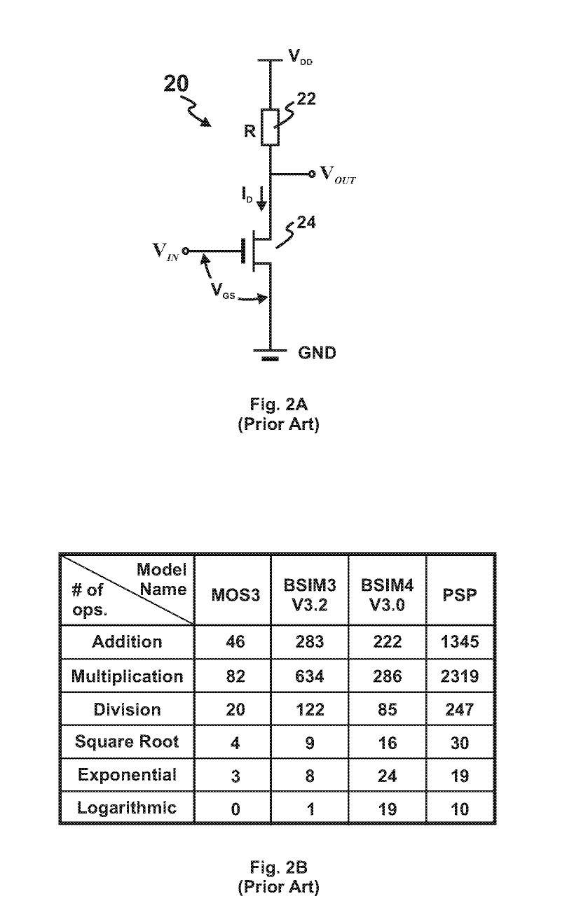

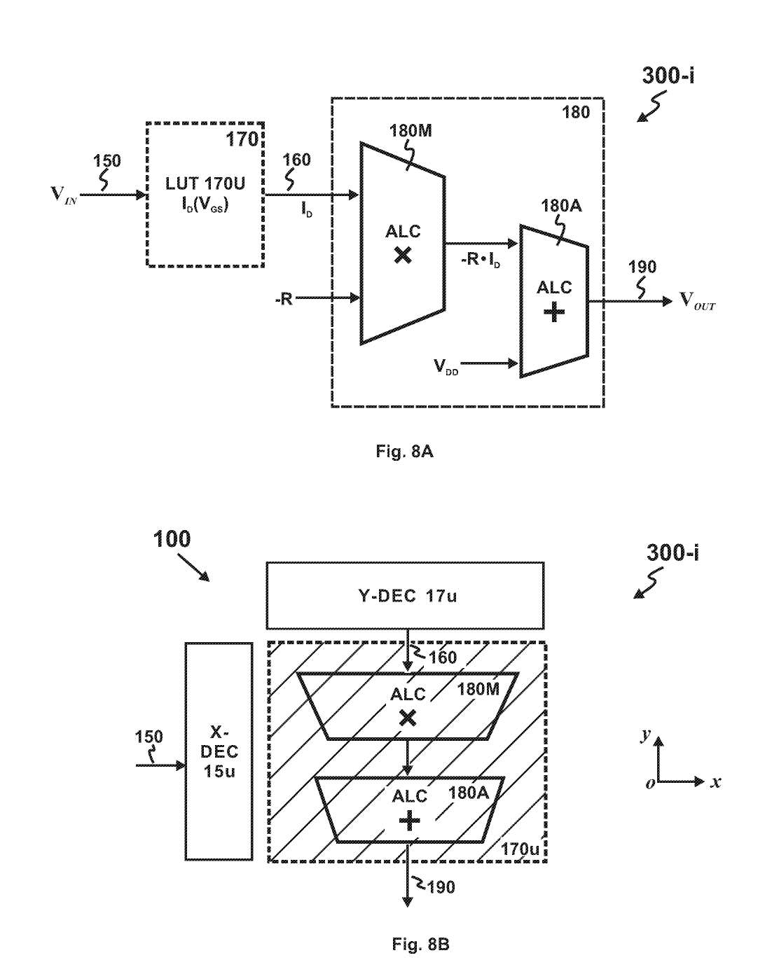

Referring now to FIGS. 8A-8B, a third preferred computing element 300-i to simulate the amplifier circuit 20 of FIG. 2A is disclosed. It uses the model-by-LUT method. As is shown in FIG. 8A, the LUT memory 170 stores an LUT 170U, while the ALC 180 comprises an adder 180A and a multiplier 180M. The LUT 170U includes the data associated with a mathematical model of the transistor 24. By using the input voltage value (V_{IN}) as an address 150 for the LUT 170U, the readout 160 of the LUT 170U is the drain-current value (I_{D}). After the I_{D} value is multiplied with the minus resistance value (−R) of the resistor 22 by the multiplier 180M, the multiplication result (−R*I_{D}) is added to the V_{DD} value by the adder 180A to generate the output voltage value (V_{OUT}) 190.

The mathematical model of the transistor 24 could take different forms. In one case, the mathematical model includes raw measurement data, i.e. the measured input-output characteristics of the transistor 24. One example is the measured drain current vs. the applied gate-source voltage (I_{D}-V_{GS}) characteristics. In another case, the mathematical model includes the smoothed measurement data. The raw measurement data could be smoothed using a purely mathematical method (e.g. a best-fit model). Alternatively, this smoothing process can be aided by a physical transistor model (e.g. a BSIM4 V3.0 transistor model). In a third case, the mathematical model includes not only the measurement data (raw or smoothed), but also its derivative values. For example, the mathematical model include not only the drain-current values of the transistor 24 (e.g. the I_{D}-V_{GS} characteristics), but also its transconductance values (e.g. the Gₘ-V_{GS} characteristics). With derivative values, polynomial interpolation can be used to improve the modeling precision using a reasonable-size LUT, as in the case of FIG. 6D.

FIG. 8B is the circuit block view on the logic level 100. The circuit blocks on the logic level 100 include an adder 180A and a multiplier 180M, as well as the X-decoders 15u and the Y-decoders 17u of the LUT 170U (for some embodiments, the decoders may be disposed on the memory level 200). On the other hand, the circuit blocks on the memory level 200 include the memory array 170u storing the LUT 170U (which is represented by a dashed line in this figure). The memory array 170u is stacked above and at least partially covers the multiplier 180M and the adder 180A. Although a single memory array 170u is shown in this figure, the preferred embodiment could use multiple memory arrays 170u.

Model-by-LUT offers many advantages. By skipping two software-decomposition steps (from mathematical models to mathematical functions, and from mathematical functions to built-in functions), it saves substantial modeling time and energy. Model-by-LUT may need less LUT than function-by-LUT. Because a transistor model (e.g. BSIM4 V3.0) has hundreds of model parameters, calculating the intermediate functions of the transistor model requires extremely large LUTs. However, if we skip function-by-LUT (namely, skipping the transistor models and the associated intermediate functions), the transistor behaviors can be described using only three parameters (including the gate-source voltage V_{GS}, the drain-source voltage V_{DS}, and the body-source voltage V_{BS}). Describing the mathematical models of the transistor 24 requires relatively small LUTs.

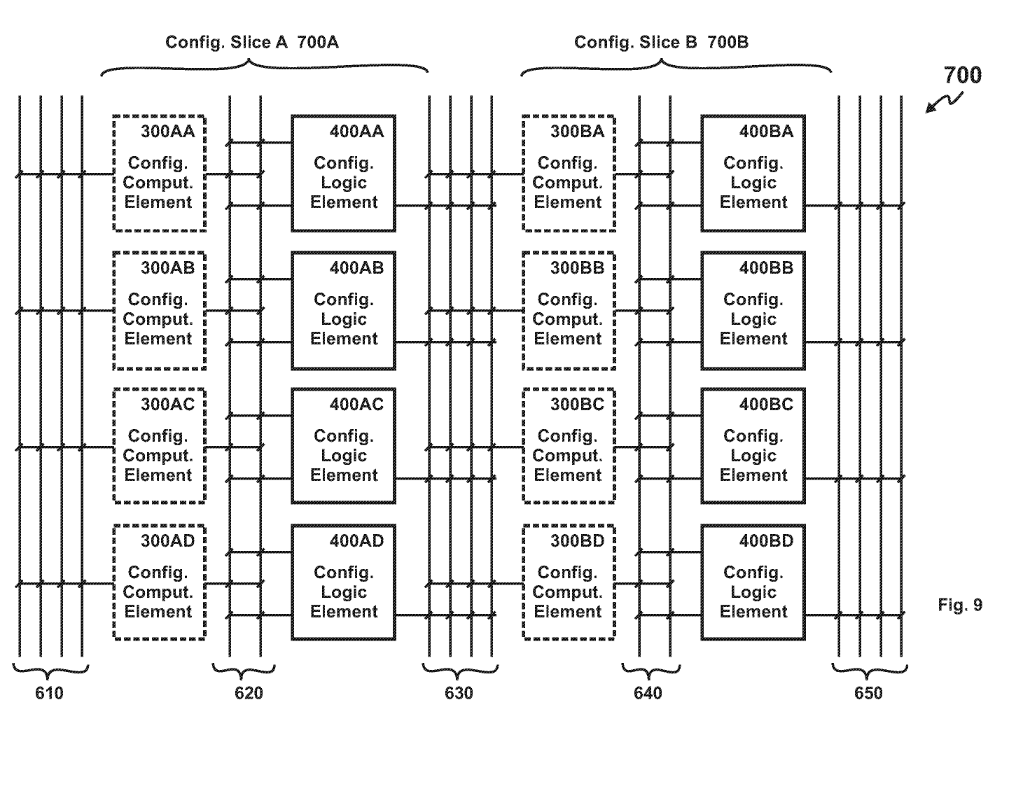

Referring now to FIG. 9, a preferred configurable processor 700 is disclosed. It is a configurable gate array 700 and comprises first and second configurable slices 700A, 700B. Each configurable slice (e.g. 700A) comprises a first array of configurable computing elements (e.g. 300AA-300AD) and a second array of configurable logic elements (e.g. 400AA-400AD). A configurable channel 620 is placed between the first array of configurable computing elements (e.g. 300AA-300AD) and the second array of configurable logic elements (e.g. 400AA-400AD). The configurable channels 610, 630, 650 are also placed between different configurable slices 700A, 700B. The configurable channels 610-650 comprise an array of configurable interconnects (represented by slashes at the cross-points in each configurable channel). For those skilled in the art, besides configurable channels, the sea-of-gates architecture may also be used. The configurable logic elements and the configurable interconnects are similar to those disclosed in Freeman (U.S. Pat. No. 4,870,302). Each configurable logic element can selectively realize any one of a plurality of logic operations (including shift, logic NOT, logic AND, logic OR, logic NOR, logic NAND, logic XOR, addition “+”, and subtraction “−”). Each configurable interconnect can selectively couple or de-couple at least one interconnect line.

FIG. 10 discloses an instantiation of the preferred configurable processor 700 for realizing e=a·sin(b)+c·cos(d). The configurable interconnects in the configurable channel 610-650 use the same convention as Freeman: the interconnect with a dot means that the interconnect is connected; the interconnect without dot means that the interconnect is not connected; a broken interconnect means that two broken sections are un-coupled. In this preferred implementation, the configurable computing element 300AA is configured to realize the function log( ) whose result log(a) is sent to a first input of the configurable logic element 400A. The configurable computing element 300AB is configured to realize the function log[sin( )], whose result log[sin(b)] is sent to a second input of the configurable logic element 400A. The configurable logic element 400A is configured to realize addition, whose result log(a)+log[sin(b)] is sent the configurable computing element 300BA. The configurable computing element 300BA is configured to realize the function exp( ) whose result exp{log(a)+log[sin(b)]}=a·sin(b) is sent to a first input of the configurable logic element 400BA. Similarly, through proper configurations, the results of the configurable computing elements 300AC, 300AD, the configurable logic elements 400AC, and the configurable computing element 300BC can be sent to a second input of the configurable logic element 400BA. The configurable logic element 400BA is configured to realize addition, whose result a·sin(b)+c·cos(d) is sent to the output e. Apparently, by changing configuration, the configurable processor 700 can realize other mathematical functions.

The preferred configurable processor 700 is particularly suitable for realizing complex functions (with multiple independent variables). If only LUT is used to realize the above 4-variable function, i.e. e=a·sin(b)+c·cos(d), an enormous LUT of 2¹⁶*2¹⁶*2¹⁶*2¹⁶*16=256Eb is needed even for half precision, which is impractical. Using the preferred configurable processor 700, only 8 Mb LUT (including 8 configurable computing elements, each with 1 Mb capacity) is needed to realize a 4-variable function.

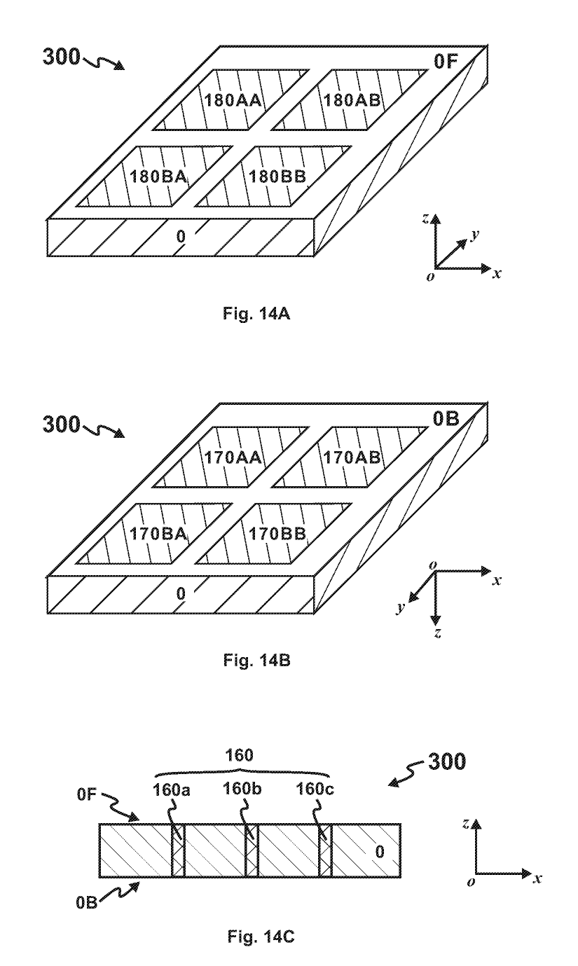

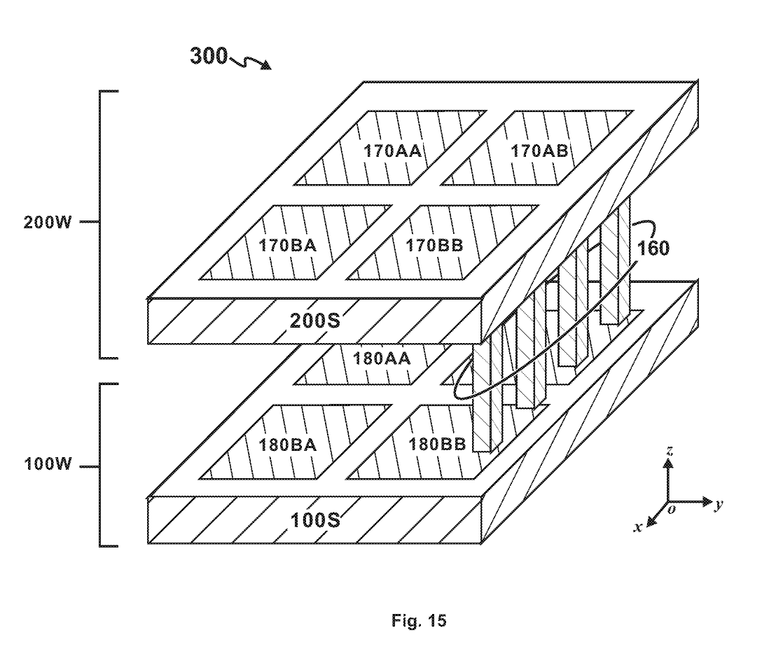

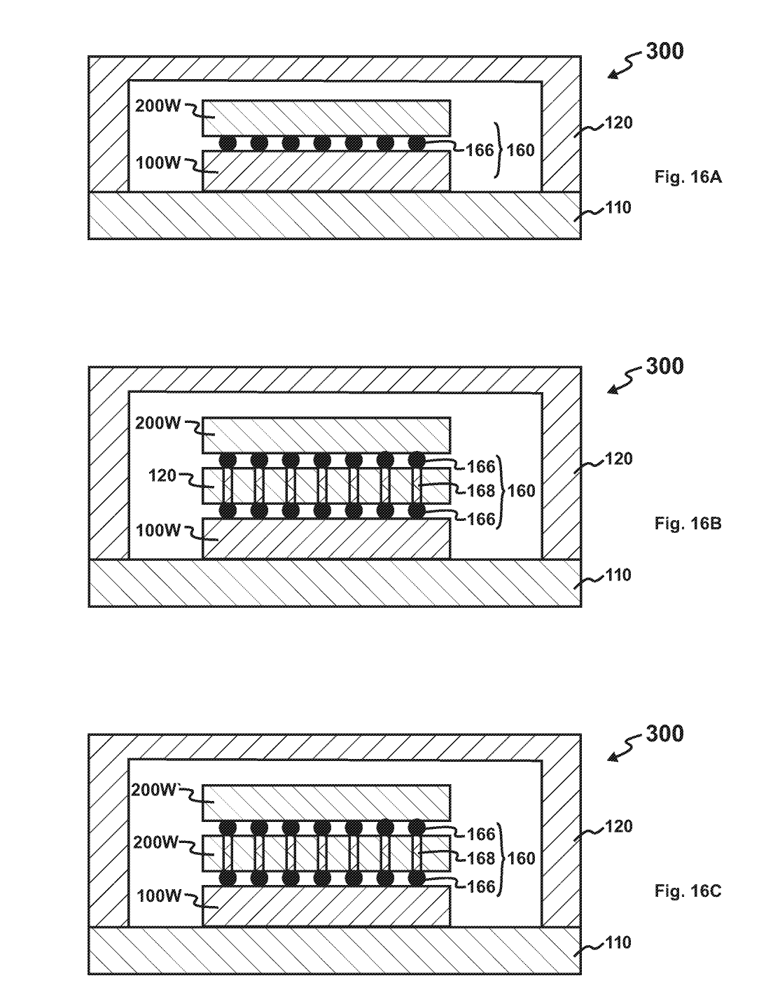

In the preferred computing element 300-i, the ALC 180 and the LUT memory 170 are disposed on different physical levels. To be more specific, the memory cells of the LUT memory 170 are disposed on at least a memory level 200, the logic transistors of the ALC 180 are disposed on at least a logic level 100, wherein the memory level 200 and the logic level 100 are different physical levels. In one preferred monolithic MBC-processor, both the memory cells and the logic transistors are disposed on the same side of a same semiconductor substrate, but the memory cells are stacked above the logic transistors (FIGS. 11A-13C). In another preferred monolithic MBC-processor, the memory cells and the logic transistors are disposed on different sides of a same semiconductor substrate (FIGS. 14A-14C). In yet another preferred MBC-processor package, the memory cells and the logic transistors are disposed on different dice of a same package (FIGS. 15-16C).

Referring now to FIGS. 11A-13C, several preferred MBC-processors 300 comprising three-dimensional memory (3D-M) are disclosed. The preferred MBC-processor 300 is a monolithic integrated circuit comprising a single semiconductor substrate 0. The ALC 180 is formed on the semiconductor substrate 0, while at least a 3D-M array 170 is stacked above the ALC 180. The 3D-M gets its name because its memory cells are distributed in a three-dimensional (3-D) space.

Based on the orientation of the memory cells, the 3D-M can be categorized into horizontal 3D-M (3D-M_{H}) and vertical 3D-M (3D-M_{V}). In a 3D-M_{H}, all address lines are horizontal. The memory cells form a plurality of horizontal memory levels which are vertically stacked above each other. A well-known 3D-M_{H} is 3D-XPoint. In a 3D-M_{V}, at least one set of the address lines are vertical. The memory cells form a plurality of vertical memory strings which are placed side-by-side on/above the substrate. A well-known 3D-M_{V} is 3D-NAND. In general, the 3D-M_{H} (e.g. 3D-XPoint) is faster, while the 3D-M_{V} (e.g. 3D-NAND) is denser.

Based on the programming methods, the 3D-M can be categorized into 3-D writable memory (3D-W) and 3-D printed memory (3D-P). The 3D-W cells are electrically programmable. Based on the number of programming allowed, the 3D-W can be further categorized into three-dimensional one-time-programmable memory (3D-OTP) and three-dimensional multiple-time-programmable memory (3D-MTP). Types of the 3D-MTP cell include flash-memory cell, memristor, resistive random-access memory (RRAM or ReRAM) cell, phase-change memory (PCM) cell, programmable metallization cell (PMC), conductive-bridging random-access memory (CBRAM) cell, and the like.

For the 3D-P, data are recorded into the 3D-P cells using a printing method during manufacturing. These data are fixedly recorded and cannot be changed after manufacturing. The printing methods include photo-lithography, nano-imprint, e-beam lithography, DUV lithography, and laser-programming, etc. An exemplary 3D-P is three-dimensional mask-programmed read-only memory (3D-MPROM), whose data are recorded by photo-lithography. Because a 3D-P cell does not require electrical programming and can be biased at a larger voltage during read than the 3D-W cell, the 3D-P is faster.

FIGS. 11A-11B disclose two preferred MBC-processors 300 comprising at least a 3D-M_{H} array. FIG. 11A discloses a preferred MBC-processor 300 comprising at least a 3D-W array. It comprises a substrate circuit 0K formed on the substrate 0. The ALC 180 is a portion of the substrate circuit 0K. A first memory level 16A is stacked above the substrate circuit 0K, with a second memory level 16B stacked above the first memory level 16A. The substrate circuit 0K includes the peripheral circuits of the memory levels 16A, 16B. It comprises transistors 0t and the associated interconnect 0M. Each of the memory levels (e.g. 16A, 16B) comprises a plurality of first address-lines (i.e. y-lines, e.g. 2a, 4a), a plurality of second address-lines (i.e. x-lines, e.g. 1a, 3a) and a plurality of 3D-W cells (e.g. 6aa). The first and second memory levels 16A, 16B are coupled to the ALC 180 through contact vias 1av, 3av, respectively. Coupling the 3D-M array 170 with the ALC 180, the contact vias 1av, 3av are collectively referred to as inter-level connections 160.

The 3D-W cell 5aa comprises a programmable layer 12 and a diode layer 14. The programmable layer 12 could be an OTP layer (e.g. an antifuse layer, which can be programmed once and is used for the 3D-OTP) or a re-programmable layer (which is used for the 3D-MTP). The diode layer 14 is broadly interpreted as any layer whose resistance at the read voltage is substantially lower than when the applied voltage has a magnitude smaller than or polarity opposite to that of the read voltage. The diode could be a semiconductor diode (e.g. p-i-n silicon diode), or a metal-oxide (e.g. TiO₂) diode.

FIG. 11B discloses a preferred MBC-processor 300 comprising at least a 3D-P array. It has a structure similar to that of FIG. 11A except for the memory cells. The 3D-P has at least two types of memory cells: a high-resistance 3D-P cell 5aa, and a low-resistance 3D-P cell 5ac. The low-resistance 3D-P cell 5ac comprises a diode layer 14, while the high-resistance 3D-P cell 5aa comprises at least a high-resistance layer 13. The diode layer 14 is similar to that in the 3D-W. The high-resistance layer 13, on the other hand, could simply be a layer of insulating dielectric (e.g. silicon oxide, or silicon nitride). It is physically removed from the low-resistance 3D-P cell 5ac during manufacturing.

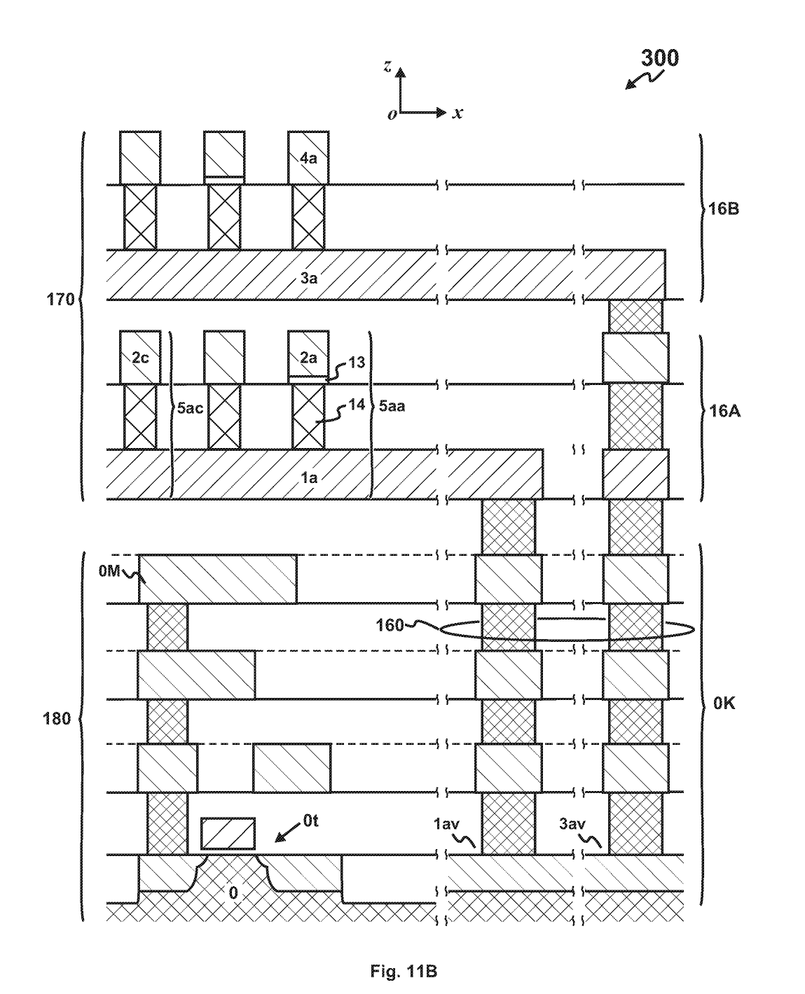

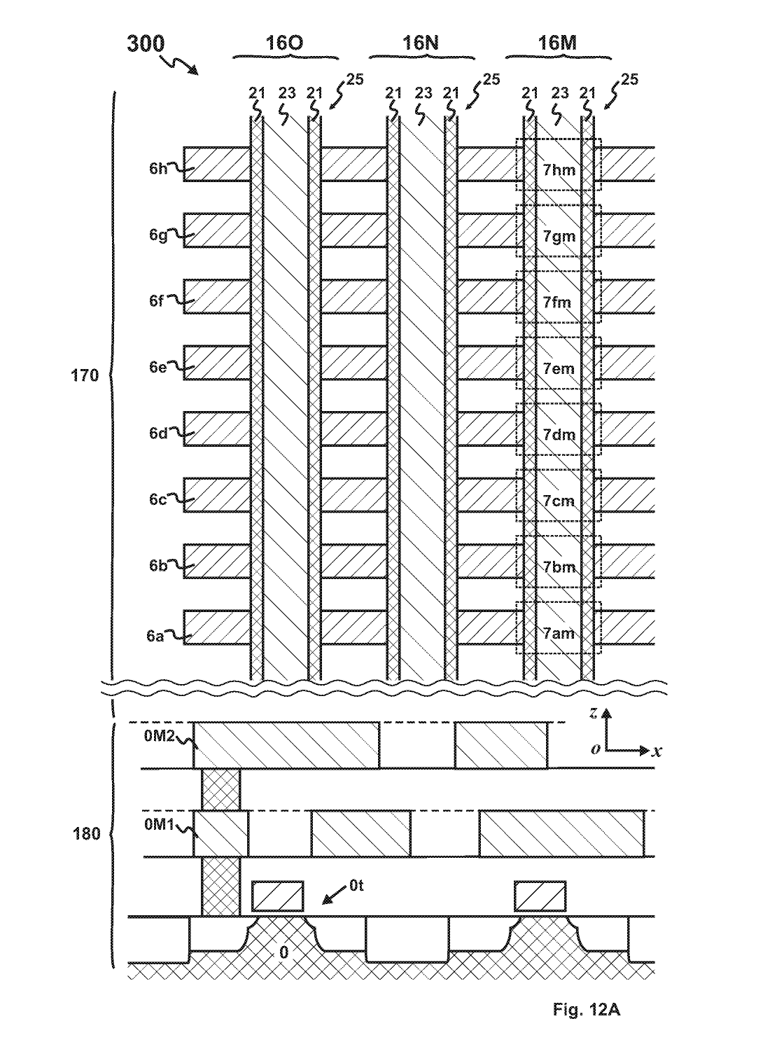

FIGS. 12A-12B disclose two preferred MBC-processors 300 comprising at least a 3D-M_{V} array. Because the 3D-M_{V} has the largest storage density among semiconductor memories, it can store the LUTs for a large number of mathematical functions and/or the LUTs with a high precision.

The preferred 3D-M_{V} array in FIG. 12A is based on vertical diodes or diode-like devices. In this preferred embodiment, the 3D-M_{V} array comprises a plurality of vertical memory strings 16M-16O placed side-by-side. Each memory string (e.g. 16M) comprises a plurality of vertically stacked memory cells (e.g. 7am-7hm). The 3D-M_{V} array comprises a plurality of horizontal address lines (word lines) 6a-6h which are vertically stacked above each other. After etching through the horizontal address lines 6a-6h to form a plurality of vertical memory wells 25, the sidewalls of the memory wells 25 are covered with a programmable layer 21. The memory wells 25 are then filled with a conductive materials to form vertical address lines (bit lines) 23. The conductive materials could comprise metallic materials or doped semiconductor materials. The memory cells 7am-7hm are formed at the intersections of the word lines 6a-6h and the bit line 23. The programmable layer 21 could be one-time-programmable (OTP, e.g. an antifuse layer) or multiple-time-programmable (MPT, e.g. a resistive RAM layer).

To minimize interference between memory cells, a diode is preferably formed between the word line and the bit line. This diode may be formed by the programmable layer 21 per se, which could have an electrical characteristic of a diode. Alternatively, this diode may be formed by depositing an extra diode layer on the sidewall of the memory well (not shown in this figure). As a third option, this diode may be formed naturally between the word line and the bit line, i.e. to form a built-in junction (e.g. P-N junction, or Schottky junction) between them.

The preferred 3D-M_{V} array in FIG. 12B is based on vertical transistors or transistor-like devices. In this preferred embodiment, the 3D-M_{V} array comprises a plurality of vertical memory strings 16X, 16Y placed side-by-side. Each memory string (e.g. 16X) comprises a plurality of vertically stacked memory cells (e.g. 9ax-9hx). Each memory cell (e.g. 9fx) comprises a vertical transistor, which includes a gate 31, a storage layer 33 and a vertical channel 35. The storage layer 33 could comprise oxide-nitride-oxide layers, oxide-poly silicon-oxide layers, or the like. The vertical channels 35 of the memory cells 9ax-9hx collectively form a vertical address line. This preferred 3D-M_{V} array is a 3D-NAND and its manufacturing details are well known to those skilled in the art.

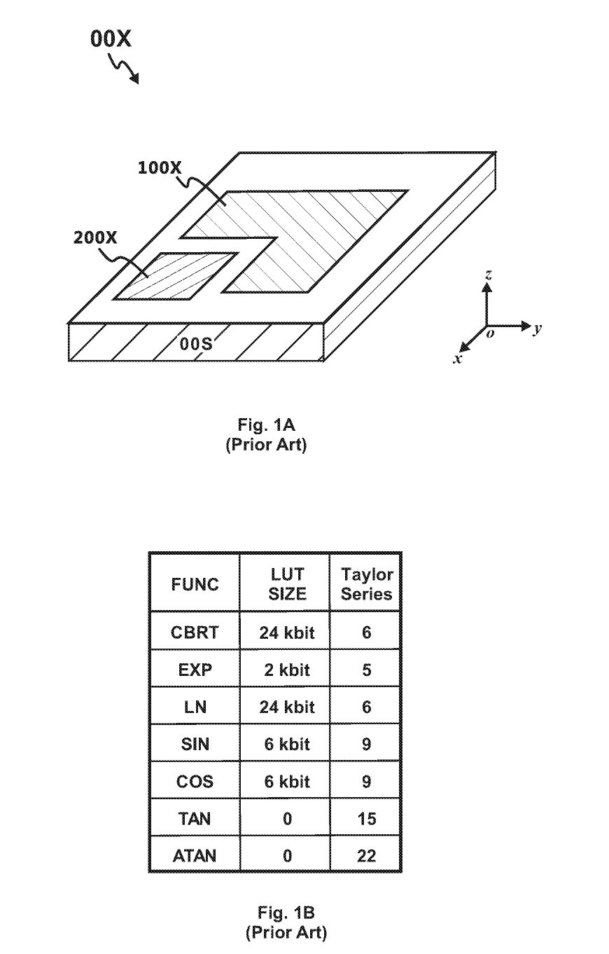

In the preferred embodiments of FIGS. 11A-12B, because the contact vias 1av, 3av coupling the 3D-M array 170 and the ALC 180 are short (on the order of an um in length) and numerous (thousands at least), the inter-level connections 160 have a much larger bandwidth than the conventional processor 00X. As the 2-D integration places the logic circuit 100X and the memory circuit 200X side-by-side on the substrate 00S, the interconnects coupling them are much longer (hundreds of ums in length) and fewer (hundreds at most) (FIG. 1A).

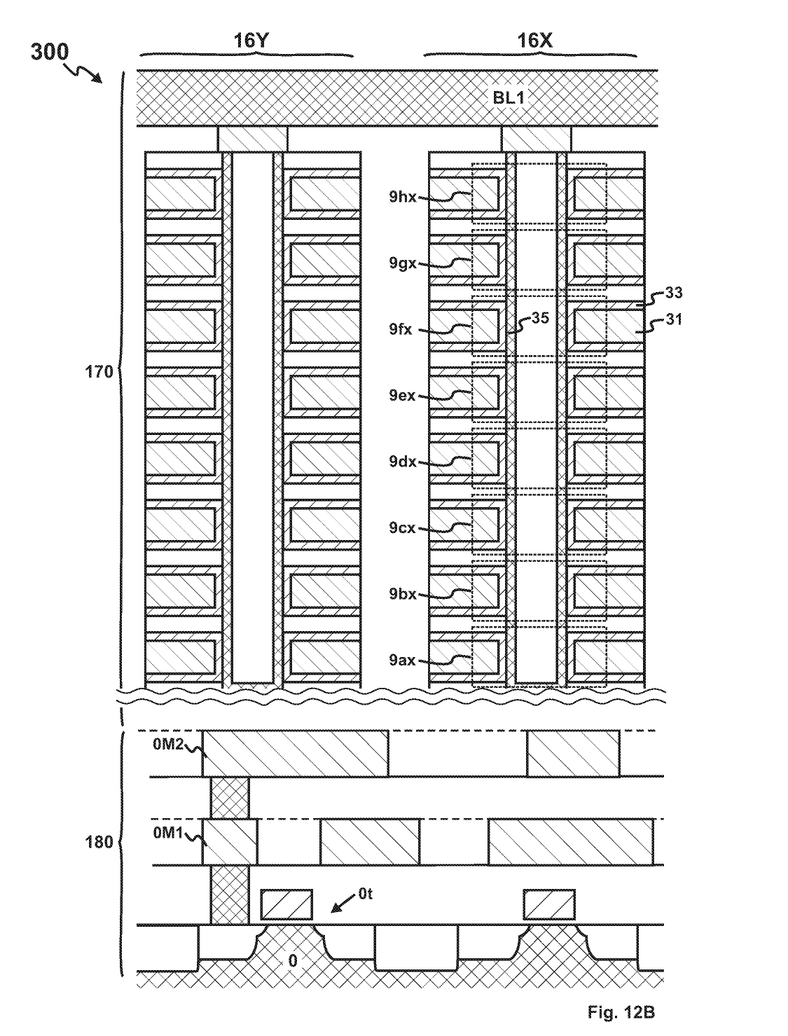

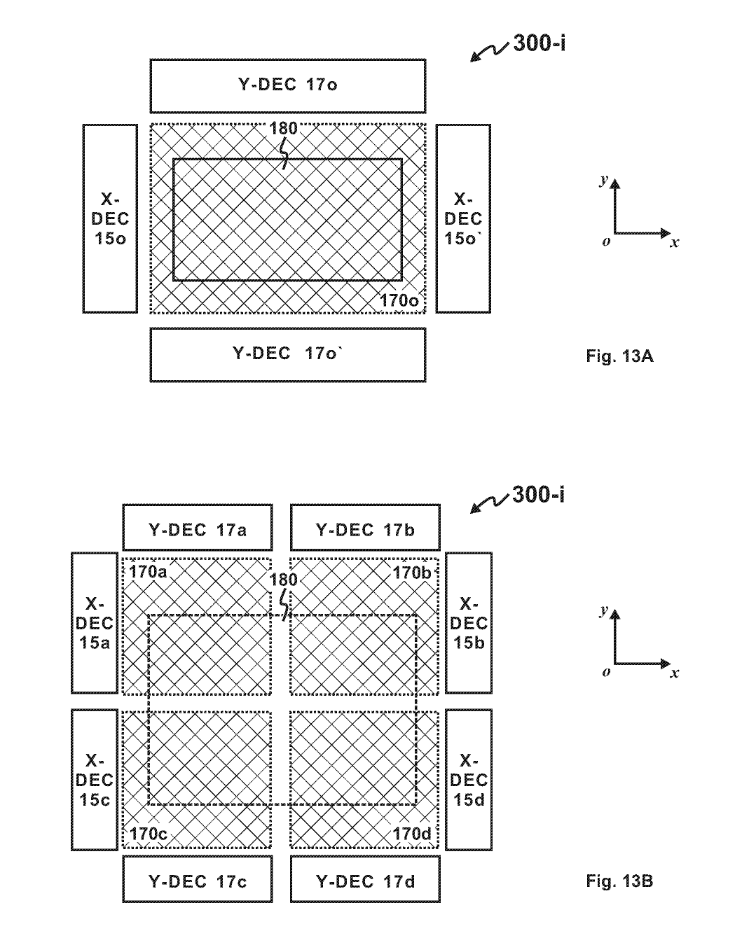

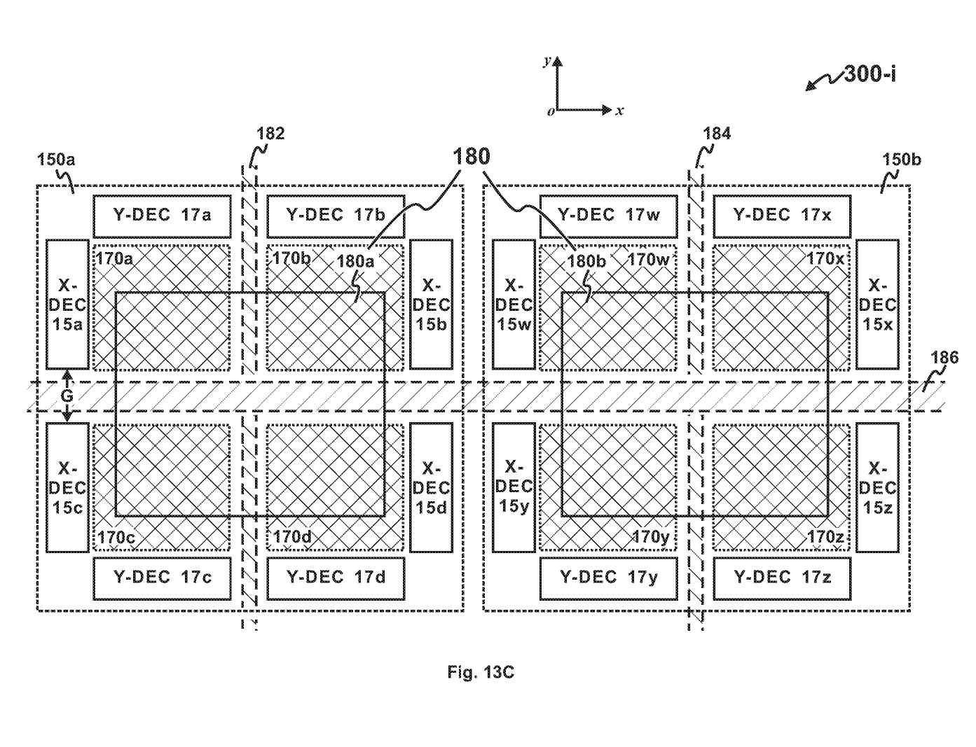

FIGS. 13A-13C show relative placement between the ALC 180 and the 3D-M arrays 170 for three preferred computing elements 300-i. Although they are shown for the 3-D integration of FIGS. 11A-12B, these placements could be applied to the two-sided integration of FIGS. 14A-14C and the 2.5-D integration of FIGS. 15-16C. In the embodiment of FIG. 13A, the ALC 180 is coupled with a single 3D-M array 170o and processes the LUT data stored therein. The ALC 180 is covered by the 3D-M array 170o. The 3D-M array 170o has four peripheral circuits, including X-decoders 15o, 15o′ and Y-decoders 17o, 17o′. The ALC 180 is bound by these four peripheral circuits. As the 3D-M array 170o is stacked above the substrate circuit 0K and does not occupy any substrate area, its projection on the substrate 0 is shown by dashed lines.

In the embodiment of FIG. 13B, the ALC 180 is coupled with four 3D-M arrays 170a-170d and processes the LUT data stored therein. Different from FIG. 13A, each 3D-M array (e.g. 170a) has two peripheral circuits (e.g. X-decoder 15a and Y-decoder 17a). The ALC 180 is bound by eight peripheral circuits (including X-decoders 15a-15d and Y-decoders 17a-17d) and located below four 3D-M arrays 170a-170d. Apparently, the ALC 180 of FIG. 13B could be four times as large as that of FIG. 13A.

In the embodiment of FIG. 13C, the ALC 180 is coupled with eight 3D-M arrays 170a-170d, 170w-170z and processes the LUT data stored therein. These 3D-M arrays are divided into two sets: a first set 150a includes four 3D-M arrays 170a-170d, and a second set 150b includes four 3D-M arrays 170w-170z. Below the four 3D-M arrays 170a-170d of the first set 150a, a first component 180a of the ALC 180 is formed. Similarly, below the four 3D-M array 170w-170z of the second set 150b, a second component 180b of the ALC 180 is formed. In this embodiment, adjacent peripheral circuits (e.g. adjacent x-decoders 15a, 15c, or, adjacent y-decoders 17a, 17b) are separated by physical gaps G. These physical gaps allow the formation of the routing channel 182, 184, 186, which provide coupling between different components 180a, 180b, or between different ALCs 180a, 180b. Apparently, the ALC 180 of FIG. 13C could be eight times as large as that of FIG. 13A.

Because the 3D-M array 170 is stacked above the ALC 180, this type of vertical integration is referred to as three-dimensional (3-D) integration. The 3-D integration has a profound effect on the computational density of the preferred MBC-processor 300. Because the 3D-M array 170 does not occupy any substrate area 0, the footprint of the computing element 300-i is roughly equal to that of the ALC 180. This is much smaller than a conventional processor 00X, whose footprint is roughly equal to the sum of the footprints of the logic circuit 100X and the memory circuit 200X. By moving the LUT memory 170 from aside to above, the computing element 300-i becomes smaller. The preferred MBC-processor 300 would contain more computing elements 300-i, become more computationally powerful and support massive parallelism.

The 3-D integration also has a profound effect on the computational complexity of the preferred MBC-processor 300. For a conventional processor 00X, the total LUT capacity is less than 100 kb. In contrast, the total LUT capacity for the preferred MBC-processor 300 could reach 100 Gb (for example, a 3D-XPoint die has a storage capacity of 128 Gb). Consequently, a single MBC-processor die 300 could support as many as 10,000 built-in functions, which are significantly more than the conventional processor 00X.

Referring now to FIGS. 14A-14C, a preferred MBC-processor die 400 using two-sided integration is disclosed. It is a monolithic integrated circuit comprising a single semiconductor substrate 0. The substrate 0 has a front side 0F (towards the +z direction) and a back side 0B (towards the −z direction). In this preferred embodiment, the ALCs 180AA-180BB are formed at the front side 0F of the substrate 0 (FIG. 14A), while the memory arrays 170AA-170BB of the LUT memory 170 are formed at the back side 0B of the substrate 0 (FIG. 14B). They are coupled through a plurality of through-substrate vias 160 (including 160a-160c) (FIG. 14C). Examples of the through-substrate vias include through-silicon vias (TSV). Alternatively, the memory arrays 170AA-170BB are formed at the front side 0F, while the ALCs 180AA-180BB are formed at the back side 0B.

This type of integration, i.e. forming the ALCs 180AA-180BB and the memory arrays 170AA-170BB on different sides of the substrate 0, is referred to as two-sided integration. The two-sided integration can improve computational density and computational complexity. With the 2-D integration, the die size of the conventional processor 00X is the sum of those of the logic circuit 100X and the memory circuit 200X. With the two-sided integration, the memory arrays 170AA-170BB are moved from aside to the other side. This leads to a smaller die size and therefore, a higher computational density and a better computational complexity. In addition, because the memory transistors in the memory arrays 170AA-170BB and the logic transistors in the ALCs 180AA-180BB are formed on different sides of the substrate 0, their manufacturing processes can be optimized separately.

Referring now to FIGS. 15-16C, several preferred MBC-processor packages 300 are disclosed. In FIG. 15, the preferred MBC-processor package 300 comprises a memory die 200W and a logic die 100W. The memory die 200W comprises a first semiconductor substrate 200S and memory arrays 170AA-170BB disposed thereon. Each memory array (e.g. 170AA) stores at least a portion of an LUT for a math function. On the other hand, the logic die 100W comprises a second semiconductor substrate 1005 and an array of ALCs 180AA-180BB disposed thereon. Each ALC (e.g. 180AA) performs at least one arithmetic operation on selected LUT data. The memory die 200W and the logic die 100W are located in a same package. In this preferred embodiment, the memory die 200W is stacked on/above the logic die 100W. The memory die 200W and the logic die 100W are communicatively coupled by a plurality of inter-die connections 160. Exemplary inter-die connections include micro-bumps and through-silicon-vias (TSV).

FIGS. 16A-16C show three preferred MBC-processor packages 300. These preferred embodiments are located in multi-chip packages (MCP). Among them, the preferred MBC-processor package 300 in FIG. 16A comprises two separate dice: a memory die 200W and a logic die 100W. The dice 200W, 100W are stacked on the package substrate 110 and located in a same package 120. Micro-bumps 166 act as the inter-die connections 160 and provide electrical coupling between the dice 200W, 100W. In this preferred embodiment, the memory die 200W is stacked on the logic die 100W; the memory die 200W is flipped and then bonded face-to-face with the logic die 100W. Alternatively, the logic die 100W could be stacked on/above the memory die 200W. Either die does not have to be flipped.

The preferred MBC-processor package 300 in FIG. 16B comprises a memory die 200W, an interposer 120 and a logic die 100W. The interposer 120 comprise a plurality of through-silicon vias (TSV) 168. The TSVs 168 provide electrical couplings between the memory die 200W and the logic die 100W. They offer more freedom in design and facilitate heat dissipation. In this preferred embodiment, the TSVs 168 and the micro-bumps 166 collectively form the inter-die connections 160.

The preferred MBC-processor package 300 in FIG. 16C comprises at least two memory dice 200W, 20W′ and a logic die 100W. These dice 200W, 200W′, 100W are separate dice and located in a same package 120. Among them, the memory die 200W′ is stacked on the memory die 200W, while the memory die 200W is stacked on the logic die 100W. The dice 200W, 200W′, 100W are electrically coupled through the TSVs 168 and the micro-bumps 166. Apparently, the LUT in FIG. 16C has a large capacity than that in FIG. 16A. Similarly, the TSVs 168 and the micro-bumps 166 collectively form the inter-die connections 160.

Because it is not monolithic (i.e. the memory die 200W and the logic die 100W are separate dice in a same package), this type of integration is generally referred to as 2.5-D integration. The 2.5-D integration excels the conventional 2-D integration in many aspects. First of all, because the 2.5-D integration moves the memory arrays from aside to above, the preferred MBC-processor package 300 is smaller and computationally more powerful than the conventional processor. Secondly, because they are physically close and can be coupled by a large number of inter-die connections 160, the memory die 200W and the logic die 100W have a larger communication bandwidth. Thirdly, the 2.5-D integration benefits manufacturing process. Because the memory die 200W and the logic die 100W are separate dice, their manufacturing processes can be individually optimized.

While illustrative embodiments have been shown and described, it would be apparent to those skilled in the art that many more modifications than that have been mentioned above are possible without departing from the inventive concepts set forth therein. For example, the processor could be a micro-controller, a controller, a central processing unit (CPU), a digital signal processor (DSP), a graphic processing unit (GPU), a network-security processor, an encryption/decryption processor, an encoding/decoding processor, a neural-network processor, or an artificial intelligence (AI) processor. These processors can be found in consumer electronic devices (e.g. personal computers, video game machines, smart phones) as well as engineering machines, scientific workstations and server computers. The invention, therefore, is not to be limited except in the spirit of the appended claims.

1-20. (canceled)

21. A processor for implementing a mathematical function, comprising:
at least first and second memory arrays on a memory level, wherein said first memory array stores at least a first portion of a first look-up table (LUT) for a first non-arithmetic function; and, said second memory array stores at least a second portion of a second LUT for a second non-arithmetic function;
at least an arithmetic logic circuit (ALC) on a logic level for performing at least an arithmetic operation on selected data from said first LUT or said second LUT, wherein said logic level is a different physical level than said memory level; and
means for communicatively coupling said first or second memory array with said ALC;
wherein said mathematical function is a combination of at least said first and second non-arithmetic functions.

22. The processor according to claim 21, wherein each of said first and second non-arithmetic functions is a mathematical function whose operations are more than arithmetic operations performable by said ALC.

23. The processor according to claim 22, wherein said arithmetic operations performable by said ALC consist of addition, subtraction and multiplication.

24. The processor according to claim 21, wherein said first memory array or said second memory array at least partially overlaps with said ALC.

25. The processor according to claim 21, wherein said first LUT includes the functional values of said mathematical function; and, said second LUT includes the derivative values of said mathematical function.

26. The processor according to claim 21, wherein said mathematical function is a composite function of said first and second non-arithmetic functions.

27. The processor according to claim 21, wherein said first non-arithmetic function has a first independent variable; said second non-arithmetic function has a second independent variable; and, said mathematical function has at least said first and second independent variables.

28. The processor according to claim 21, further comprising a single semiconductor substrate, wherein said ALC is disposed on said semiconductor substrate; said first and second memory arrays are three-dimensional memory (3D-M) arrays stacked above said ALC; and, said ALC and said 3D-M arrays are communicatively coupled by a plurality of contact vias.

29. The processor according to claim 21, further comprising a single semiconductor substrate with first and second sides, wherein said ALC is disposed on said first side; said first and second memory arrays are disposed on said second side; and, said first and second sides are coupled by a plurality of through-substrate vias through said semiconductor substrate.

30. The processor according to claim 21, wherein said ALC disposed on at least a logic die; said first and second memory arrays are disposed on at least a memory die; and, said logic die and said memory die are located in a same package.

31. The processor according to claim 21, wherein said processor is a micro-controller, a controller, a central processing unit (CPU), a digital signal processor (DSP), a graphic processing unit (GPU), a network-security processor, an encryption/decryption processor, an encoding/decoding processor, a neural-network processor, or an artificial intelligence (AI) processor.

32. A processor for implementing a mathematical function, comprising:
at least a memory array on a memory level for storing at least a portion of a look-up table (LUT) for a non-arithmetic function;
at least an arithmetic logic circuit (ALC) on a logic level for performing at least an arithmetic operation on selected data from said LUT; and
means for communicatively coupling said memory array and said ALC,
wherein said memory level and said logic level are different physical levels.

33. The processor according to claim 32, wherein said non-arithmetic function is a mathematical function whose operations are more than arithmetic operations performable by said ALC.

34. The processor according to claim 33, wherein said arithmetic operations performable by said ALC consist of addition, subtraction and multiplication.

35. The processor according to claim 32, wherein said memory array at least partially overlaps with said ALC.

36. The processor according to claim 32, wherein said LUT includes the functional values or the derivative values of said mathematical function.

37. The processor according to claim 32, further comprising a single semiconductor substrate, wherein said ALC is disposed on said semiconductor substrate; said memory array is a three-dimensional memory (3D-M) array stacked above said ALC; and, said ALC and said 3D-M array are communicatively coupled by a plurality of contact vias.

38. The processor according to claim 32, further comprising a single semiconductor substrate with first and second sides, wherein said ALC is disposed on said first side; said memory array is disposed on said second side; and, said first and second sides are coupled by a plurality of through-substrate vias through said semiconductor substrate.

39. The processor according to claim 32, wherein said ALC disposed on at least a logic die; said memory array is disposed on at least a memory die; and, said logic die and said memory die are located in a same package.

40. The processor according to claim 32, wherein said processor is a micro-controller, a controller, a central processing unit (CPU), a digital signal processor (DSP), a graphic processing unit (GPU), a network-security processor, an encryption/decryption processor, an encoding/decoding processor, a neural-network processor, or an artificial intelligence (AI) processor.
